(19) United States
(12) Patent Application Publication
(10) Pub. No.: US 2003/0038366 A1
(43) Pub. Date: Feb. 27, 2003

(54) Three-dimensional semiconductor device having plural active semiconductor components

(75) Inventor: Hiroyuki Kozono, Kanagawa-ken (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Kabushiki Kaisha Toshiba, Kanagawa-ken (JP)

(21) Appl. No.: 10/268,752

(22) Filed: Oct. 11, 2002

Related U.S. Application Data
(63) Continuation of application No. 09/264,706, filed on Mar. 9, 1999, now abandoned.

(51) Int. Cl. H05K 7/06; H01L 23/52

(52) U.S. Cl. 257/723; 257/724; 361/782; 361/783; 257/783

(57) ABSTRACT

There is disclosed a three-dimensional semiconductor device having a printed wiring board or insulating film having first and second surfaces. Semiconductor components are packed on the first surface. External terminals are mounted to the second surface. Semiconductor components or a thin-film inductor producing a large amount of heat are installed in a space on the second surface via an anisotropic conductive film. This reduces the packaging density. After packaging, the rigidity of the printed wiring board or insulating film is enhanced. Heat generated by the semiconductor components is efficiently dissipated to reduce the affects on other components.

### BACKGROUND OF THE INVENTION

1. Field of the Invention

The present invention relates to a semiconductor device comprising a printed wiring board on which active semiconductor components are packed and, more particularly, to a multilayer semiconductor device comprising a printed wiring board having a space where active semiconductor components or thin-film inductors producing large amounts of heat are received.

2. Discussion of the Background

Heretofore, ball-grid array (BGA) type semiconductor devices using printed wiring boards or insulating film have been well known. Usually, chip resistors, chip capacitors, thin-film inductors that are passive components and thin-film inductors are packed, together with a semiconductor integrated circuit, on a surface on the opposite side of external terminals, using conductive interconnects formed either on a printed wiring board or on an insulating film.

FIG. 1 is a perspective view of a first surface of the prior art semiconductor device. FIG. 2 is a perspective view of a second surface of the prior art semiconductor device. FIG. 3 is a cross-sectional view taken on line A-A′ of the semiconductor device shown in FIGS. 1 and 2. The prior art device comprises a printed wiring board 101, a plastic package 102 sealing one side of the board, and ball-like external terminals 103 mounted on the opposite side of the package 102. Metallization layers 110 are formed on both surfaces of the printed wiring board 101. Through holes are formed in the board 101. A metallization layer 111 is buried in the through holes. The metallization layers 110 on both surfaces are electrically connected via the buried metallization layer 111. A solder resist 120 is patterned on one side. The external terminals 103 are formed on those portions of the printed wiring board 101 which are at one side of the plastic package 102 and to which the solder resist 120 is not applied.

An integrated circuit (IC) 130 consisting of active semiconductor components is bonded via adhesive 131 to the surface of the printed wiring board 101 on which the plastic package 102 is formed. Terminals 135 such as bumped electrodes formed on the surfaces of the semiconductor components 130 are electrically connected with the metallization layer 110 on the printed wiring board 101 on the side of the semiconductor components by means of bonding wires 107. The semiconductor components 130, the metallization layer 110, and the bonding wires 137 are sealed by the plastic package 102.

This semiconductor device is installed on a mother board 140 that is a printed circuit board as shown in FIG. 4. A metallization layer 142 is formed on the mother board 140. The external terminals 103 of the printed wiring board 101 are connected with this metallization layer 142. When semiconductor components are connected with the metallization layer 142 of the mother board 140 with the prior art technique as shown in FIG. 4, there exist no means of controlling the height of the external terminals 103. Depending on the pitch between the interconnects formed from the metallization layer 142, adjacent external terminals may be shorted to each other as indicated by 150. Where the semiconductor components are transfer-molded, if a large amount of heat is generated, the semiconductor components are made defective.

FIG. 5 is a perspective view of the prior art semiconductor device comprising plural LSIs, discrete semiconductor components, passive components, etc. This device comprises a printed wiring board 101 having terminals 37 around the periphery, the terminals being used for making connections with the outside. Conductive interconnects 36 are formed on those portions where components are installed. Control ICs 33, 24, capacitors 35, 38, and so on are connected with the conductive interconnects 36 on the portions where the components are installed. A thin-film inductor 32 is also installed and has leads 39 connected with the conductive interconnects 36. The components on the printed wiring board 101 are sealed by a plastic package 31. Usually, the thin-film inductor 32 is rectangular in shape, i.e., its one side is greater than the other side. This makes it necessary to increase the area of the printed wiring board.

FIG. 6 is a fragmentary plan view of the semiconductor device, illustrating the state in which leads are connected with the conductive interconnects 36. Since the thin-film inductor 32 produces RF electromagnetic waves, a high current must be applied. Because the amount of current is large in this way, the plural leads are connected with the connection area 40 of the conductive interconnects 36. Although the plural leads are used, the junction area (indicated by the hatching) in the junction region is small. Therefore, the junction characteristics are poor, and the energy loss is large.

### SUMMARY OF THE INVENTION

In view of the foregoing circumstances, the present invention has been made.

It is an object of the present invention to provide a semiconductor device whose packaging density has been decreased by attaching semiconductor components or passive components to those areas which have not been used heretofore.

It is another object of the invention to increase the rigidity of a printed wiring board or insulating film when it is mounted to a mother board.

It is a further object of the invention to provide a semiconductor device which has semiconductor components producing heat and which is designed in such a way that the heat is efficiently dissipated.

The above-described objects are achieved in accordance with the teachings of the invention by a semiconductor device comprising a printed wiring board or insulating film having a first surface on which semiconductor components are packed and a second surface to which external terminals are attached, the semiconductor device being characterized in that semiconductor components or a thin-film inductor producing large amounts of heat is received in a space of the second surface and fixed using an anisotropic conductive film. External terminals are mounted on the second surface. The semiconductor components or thin-film inductor is positioned in the region that has not been used conventionally. This reduces the packaging density, enhances the rigidity of the printed wiring board or insulating film, and dissipates heat produced from the semiconductor components efficiently so that other portions are less affected by the heat.

In particular, a semiconductor device in accordance with the present invention comprises: a printed wiring board having first and second surfaces; first semiconductor integrated circuit components fabricated on the first surface of the printed wiring board; external components fabricated on the second surface of the printed wiring board and electrically connected with conductive interconnects on the printed wiring board; and second semiconductor integrated circuit components fabricated on the second surface of the printed wiring board. The second semiconductor integrated circuit components are connected with the printed wiring board via an anisotropic conductive film and electrically connected with the conductive interconnects.

The present invention also provides a semiconductor device comprising: an insulating film having a first surface on which conductive interconnects are formed and a second surface on which external terminals electrically connected with the conductive interconnects are fabricated; first semiconductor integrated circuit components formed on the first surface of the insulating film; and second semiconductor integrated circuit components fabricated on the second surface of the insulating film. The second semiconductor integrated circuit components are connected with the insulating film via the anisotropic conductive film and electrically connected with the conductive interconnects.

Furthermore, the present invention provides a semiconductor device comprising: a printed wiring board having first and second surfaces; semiconductor integrated circuit components fabricated on the first surface of the printed wiring board; external terminals formed on the second surface of the printed wiring board and electrically connected with conductive interconnects on the printed wiring board; and a thin-film inductor fabricated on the second surface of the printed wiring board. The thin-film inductor is connected with the printed wiring board via an anisotropic conductive film and electrically connected with the conductive interconnects.

Additionally, the present invention provides a semiconductor device comprising: an insulating film having a first surface on which conductive interconnects are formed and a second surface on which external terminals electrically connected with the conductive interconnects are formed; semiconductor integrated circuit components fabricated on the first surface of the insulating film; external terminals formed on the second surface of the insulating film and electrically connected with the conductive interconnects on the insulating film; and a thin-film inductor fabricated on the second surface of the insulating film. The thin-film inductor is connected with the insulating film via an anisotropic conductive film and electrically connected with the conductive interconnects.

Other objects, features, and advantages of the present invention will become apparent from the following detailed description. It should be understood, however, that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

A more complete appreciation of the invention and many of the attendant advantages thereof will be readily obtained by reference to the following detailed description when considered in connection with the accompanying drawings, wherein:

FIGS. 1 and 2 are perspective views of the prior art semiconductor device;

FIG. 3 is a cross-sectional view of the prior art semiconductor device shown in FIGS. 1 and 2;

FIG. 4 is a fragmentary cross section of the prior art semiconductor device installed on a mother board;

FIG. 5 is a perspective view of a conventional semiconductor device comprising plural kinds of components, showing the device mounted to a mother board;

FIG. 6 is an enlarged view of the pad region of the conventional semiconductor device shown in FIG. 5;

FIGS. 7 and 8 are perspective views of a semiconductor device in accordance with the present invention;

FIGS. 9-12 are cross-sectional views of the semiconductor device shown in FIGS. 7 and 8;

FIGS. 13 and 14 are perspective views of a semiconductor device in accordance with the invention;

FIG. 15 is a cross-sectional view of a semiconductor device in accordance with the invention;

FIGS. 16-18 are cross-sectional views of a semiconductor device in accordance with the invention, illustrating a process sequence for fabricating the device;

FIGS. 19-21 are cross-sectional views of a semiconductor device in accordance with the invention, illustrating a process sequence for fabricating the device;

FIGS. 22-25 are cross-sectional views of a semiconductor device in accordance with the invention, illustrating a process sequence for fabricating the device;

FIGS. 26-28 are cross-sectional views of a semiconductor device in accordance with the invention, showing the device mounted to a mother board;

FIG. 29(a) is a perspective view of a thin-film inductor installed on a semiconductor device in accordance with the invention;

FIG. 29(b) is a plan view of the thin-film inductor shown in FIG. 29(a); and

FIG. 30 is a cross-sectional view of a semiconductor device in accordance with the invention.

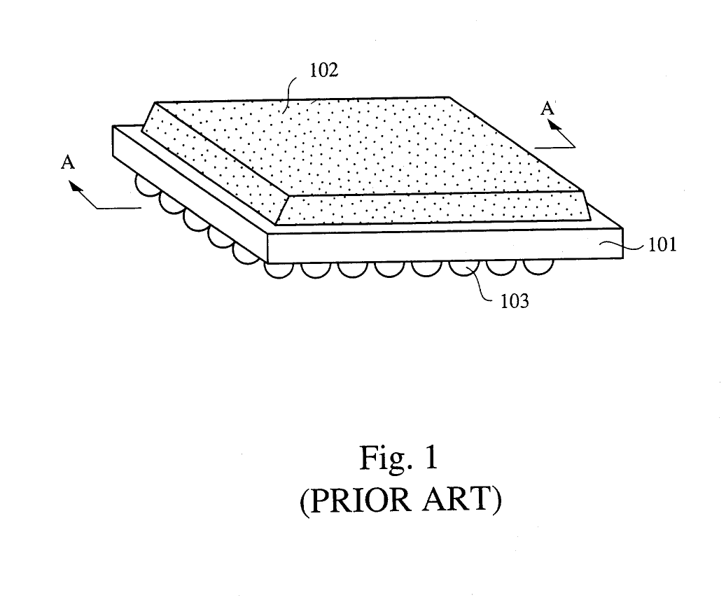

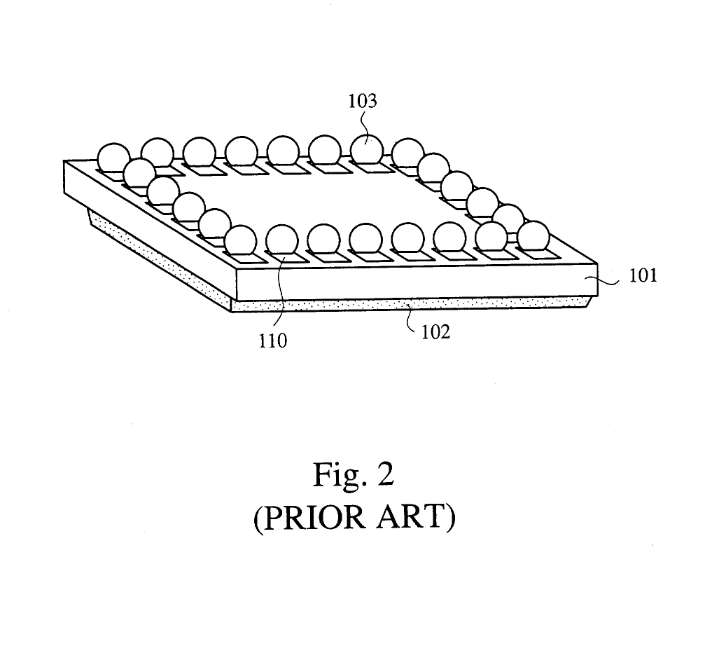

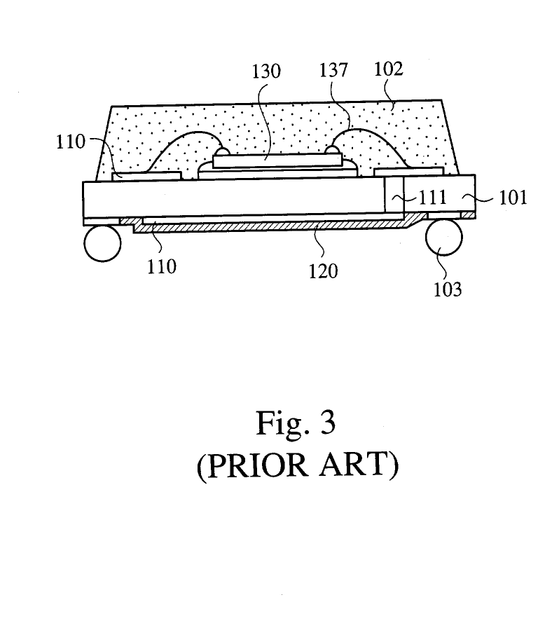

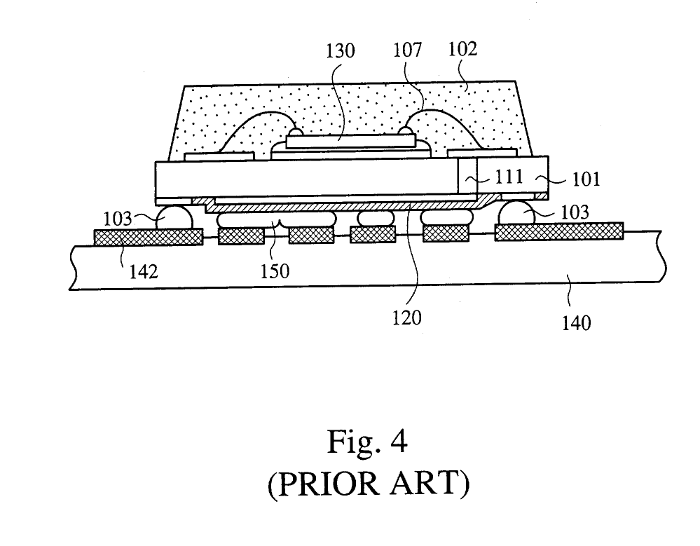

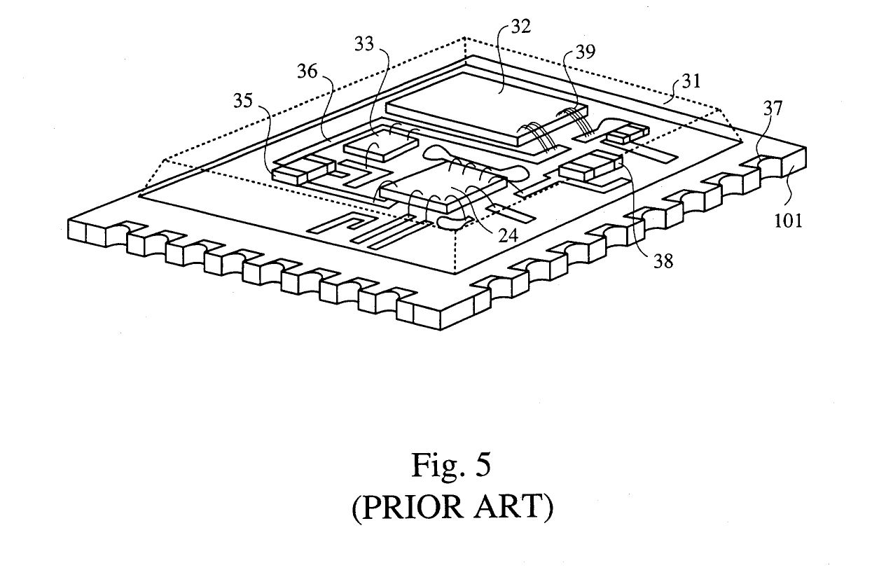

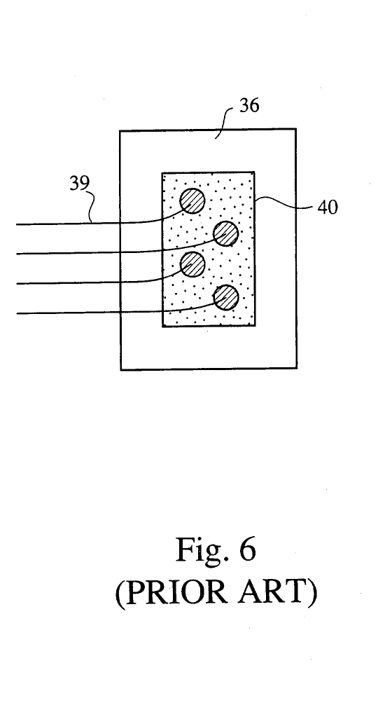

### DESCRIPTION OF THE PREFERRED EMBODIMENTS

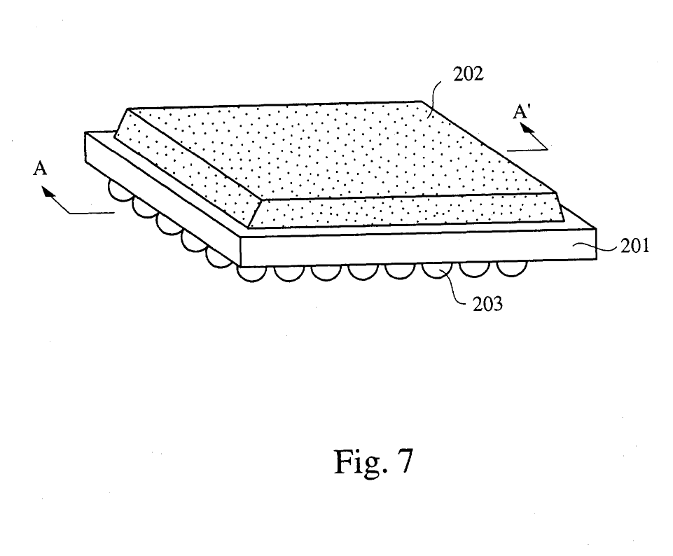

A first embodiment of the present invention is next described by referring to FIGS. 7-9. In this embodiment, a semiconductor integrated circuit is packed on a printed wiring board.

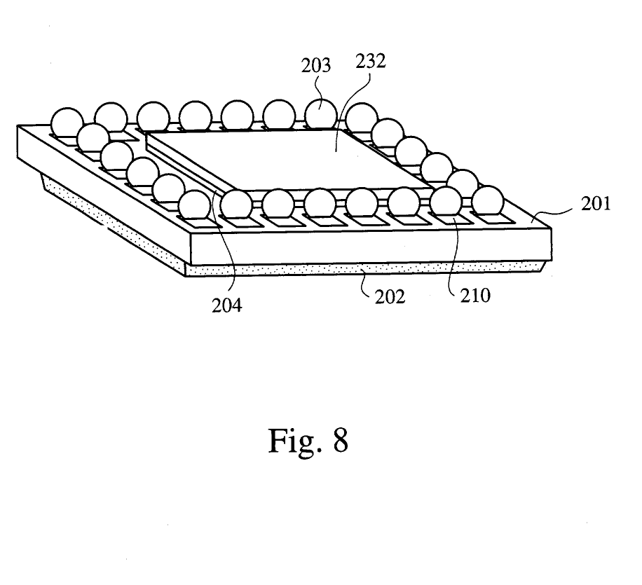

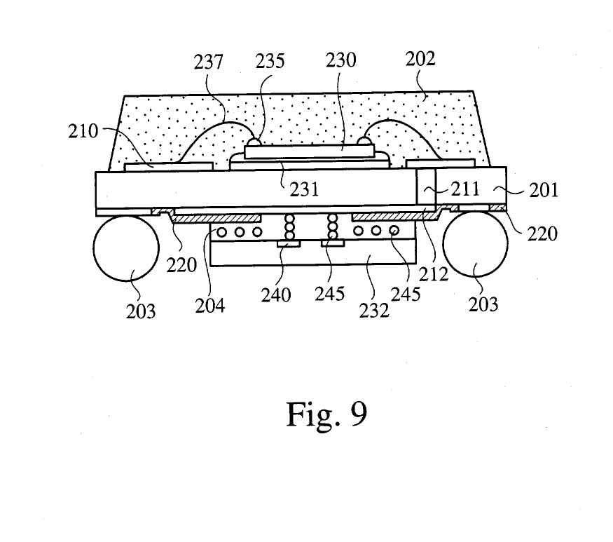

FIG. 7 is a perspective view of a semiconductor device, as viewed from a first surface on the opposite side of external terminals. FIG. 8 is a perspective view of the semiconductor device, as viewed from a second surface on the side of the external terminals. FIG. 9 is a cross-sectional view taken on line A-A′ of FIG. 7. The illustrated semiconductor device comprises a printed wiring board 201, a transfer-molded plastic package 202 sealing one side, or the first surface, of the printed wiring board 201, ball-like external terminals 203 bonded to the other side, or the second surface, and semiconductor components 232 connected to the surface on the side of the external terminals via an anisotropic conductive film 204. The semiconductor components 232 produce large amounts of heat. Conductive interconnects 210 and 212 made of aluminum are formed on opposite sides of the printed wiring board 201. Through holes are formed in the board. A metallization layer 211 is buried in the through holes. The conductive interconnects on the opposite surfaces are connected via the buried metallization layer 211. A solder resist pattern 220 is formed on the second surface. The external terminals 203 are electrically connected with those portions of the second surface of the printed wiring board 201 that are not coated with the solder resist.

Semiconductor components 230 are connected with the first surface via adhesive 231. Terminals 235 of the semiconductor components 230 are electrically connected with the conductive interconnects 210 formed on the first surface of the printed wiring board 201 by means of bonding wires 237.

The plastic package 202 coats the conductive interconnects 210 on the first surface of the printed wiring board 201, the adhesive 231, the bonding wires 237, and the semiconductor components 230. Terminals 240 of the semiconductor components 232 on the side of the external terminals, or the second surface, are electrically wired into the circuitry by metal spheres 245 inside the anisotropic conductive film 204 and connected with the conductive interconnects 212 formed on the second surface of the board 201. The anisotropic conductive film 204 consists of a film of a synthetic resin such as polyimide in which spheres of a metal such as silver are dispersed. When pressure is applied to part of the film surface, the dispersed metal spheres contact each other, creating an electrically conductive path.

In the above-described semiconductor device in accordance with the first embodiment, the external terminals 203 are arranged on the second surface of the printed wiring board. The semiconductor components 232 producing large amounts of heat are disposed in a space surrounded by the external terminals 203 and fixed via the anisotropic conductive film. This reduces the packaging density of the semiconductor device. When the semiconductor device is mounted to a mother board, the rigidity of the printed wiring board can be enhanced. Another advantage of the invention is that the heat generated by the semiconductor components 232 is efficiently dissipated. In consequence, other semiconductor components are less affected. When the semiconductor components or thin-film inductors on the side of the external terminals are bonded to the printed wiring board by the anisotropic conductive film, the bonded components or thin-film inductors are lower in height than the external terminals.

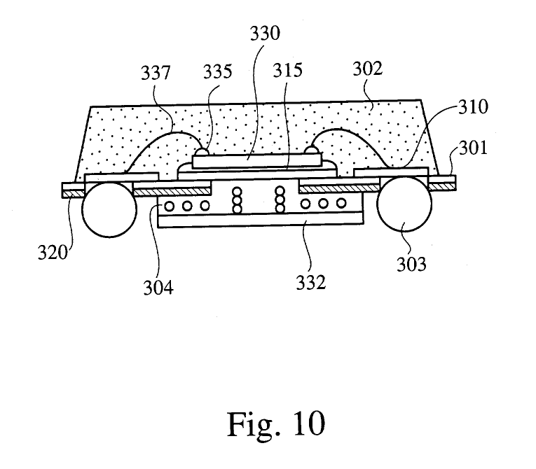

A second embodiment of the invention is next described by referring to FIG. 10, which is a cross-sectional view of a semiconductor device comprising an insulating film having metallization layers on which semiconductor components are installed. The semiconductor device comprises the insulating film 301, a plastic package 302 sealing one side, or a first surface, of the insulating film 301, ball-like external terminals 303 bonded to the other side, or a second surface, and semiconductor components 332 connected with the surface on the side of the external terminals via the anisotropic conductive film 304. The semiconductor components 332 produce large amounts of heat. Conductive interconnects 310 made of aluminum, for example, are formed on the first surface of the insulating film 301. A solder resist pattern 320 is formed on the second surface. The external terminals 303 are electrically connected with the exposed portions of the conductive interconnects 310 via holes extending through the insulating film 301 at locations of the second surface of the insulating film 301 where the solder resist is not applied.

Semiconductor components 330 are connected with the first surface of the insulating film 301 via adhesive 315. Terminals 335 of the semiconductor components 330 are electrically coupled by means of bonding wires 337 to the conductive interconnects 310 formed on the first surface. The plastic package 302 coats the conductive interconnects 310 on the first surface of the insulating film 301, the adhesive 315, the bonding wires 337, the semiconductor components 330, etc. Terminals (not shown) of the semiconductor components 330 on the side of the external terminals (second surface) are electrically connected with exposed portions 315 of the conductive interconnects 310 on the first surface by metal spheres inside the anisotropic conductive film 304. The anisotropic conductive film 304 consists of a film of a synthetic resin such as polyimide in which spheres of a metal such as silver are dispersed. When pressure is applied to a part of the film surface, the dispersed metal spheres are brought into contact with each other, creating an electrically conductive path.

In the above-described semiconductor device forming the second embodiment, the external terminals 303 are arranged on the second surface of the insulating film. The semiconductor components 332 producing large amounts of heat are disposed in the space surrounded by the external terminals 303 and fixed via the anisotropic conductive film 304. This reduces the packaging density. After packaging, the rigidity of the tape is enhanced. Another advantage of the invention is that the heat generated by the semiconductor components 332 is efficiently dissipated. In consequence, other semiconductor components are less affected.

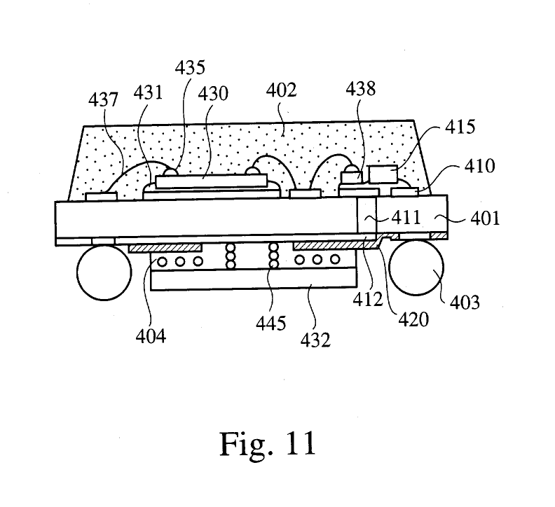

A third embodiment of the invention is next described by referring to FIG. 11. In this embodiment, a multiplicity of components are packed on a printed wiring board.

FIG. 11 is a cross-sectional view of a semiconductor device having semiconductor components packed on a printed wiring board. The illustrated semiconductor device comprises a transfer-molded plastic package 402 sealing one side (first surface) of the printed wiring board 401, ball-like external terminals 403 bonded to the other surface (second surface), and semiconductor components 432 connected with the surfaces of the external terminals via an anisotropic conductive film 404. The semiconductor components 432 produce large amounts of heat. Conductive interconnects 410 and 412 made of aluminum, for example, are formed on opposite sides of the printed wiring board 401. A buried layer of metallization 411 is formed in holes extending through the board. The conductive interconnects 410 and 412 of aluminum or other material on the opposite sides are connected together by the buried layer of metallization 411. A solder resist pattern 420 is formed on the second surface. The external terminals 403 are electrically connected with the second surface of the printed wiring board 401 to which the solder resist is not applied. Semiconductor components 430 are connected with the first surface via adhesive 431. Terminals 435 of the semiconductor components 430 are electrically coupled to the conductive interconnects 410 formed on the first surface by means of bonding wires 437.

This embodiment is characterized in that plural components such as a discrete transistor 438 and a capacitor 415 are packed on the first surface of the printed wiring board 401, in addition to the semiconductor components 430. A thin-film inductor or the like used for a DC-DC comparator can be packed on the device. The plastic package 402 coats the conductive interconnects 410 on the first surface of the insulating film 401, the adhesive 431, the bonding wires 437, a discrete transistor 410, a capacitor 415, and semiconductor components 430, etc. Terminals 404 of the semiconductor components 432 on the side of the external terminals (second surface) are electrically connected with conductive interconnects 412 on the second surface of the printed wiring board 401 by metal spheres 445 inside the anisotropic conductive film 404.

In the semiconductor device according to the third embodiment of the invention, the external terminals 403 are arrayed on the second surface of the printed wiring board. The semiconductor components 432 producing large amounts of heat are fixed with the anisotropic conductive film 404 in the space surrounded by the external terminals 403. Therefore, this reduces the packaging density of the semiconductor device. When the device is installed, the strength of the printed wiring board can be enhanced. Heat generated by the semiconductor components 432 can be effectively dissipated. Other components are less affected.

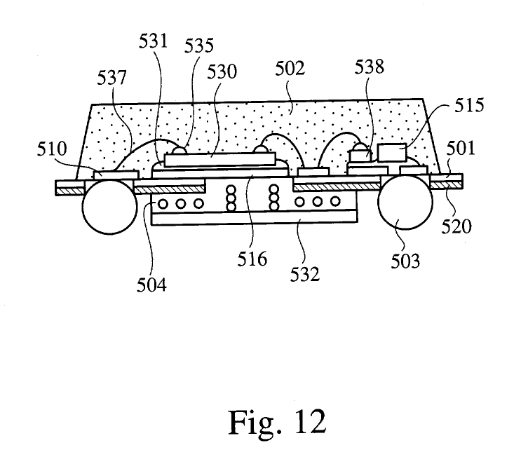

A fourth embodiment of the present invention is next described by referring to FIG. 12. In this embodiment, a multiplicity of semiconductor components are attached to tape. FIG. 12 is a cross-sectional view of a semiconductor device having semiconductor components bonded to an insulating film having conductive interconnects. The semiconductor device comprises a transfer-molded plastic package 502 sealing one side (a first surface) of the insulating film 501, ball-like external terminals 503 bonded to the other surface (a second surface), and semiconductor components 532 connected with the surfaces of the external terminals via an anisotropic conductive film 504. The semiconductor components 532 produce large amounts of heat. Conductive interconnects 510 of aluminum or other material are formed on the first surface of the insulating film 501. A solder resist pattern 520 is formed on the second surface. The external terminals 503 are formed on those portions of the second surface of the insulating film 501 to which the solder resist is not applied, and are electrically connected with the exposed portions 516 of the conductive interconnects 510 via holes extending through the film 501.

Semiconductor components 530 are connected with the first surface of the insulating film 501 via adhesive 531. Terminals 535 of the semiconductor components 530 are electrically coupled to the conductive interconnects 510 formed on the first surface by means of bonding wires 537. Discrete transistors 538 and capacitors 515 are packed on the first surface, in addition to the semiconductor components 530. The connecting electrodes of the discrete transistors 510 are electrically connected with the conductive interconnects 510 by the bonding wires 537. The plastic package 502 coats the conductive interconnects 510 on the first surface of the insulating film 501, the adhesive 531, the bonding wires 537, the discrete transistors 538, the capacitors 515, the semiconductor components 530, etc. The terminals of the semiconductor components 532 on the side of the external terminals, or on the side of the second surface, are connected with exposed portions 516 of the conductive interconnects 510 on the first surface by metal spheres inside the anisotropic conductive film 504. The anisotropic conductive film 504 consists of a film of a synthetic resin such as polyimide in which spheres of a metal such as silver are dispersed. When pressure is applied to a part of the film surface, the dispersed metal spheres come into contact with each other, creating an electrically conductive path.

In the fourth embodiment of the invention, external terminals 503 are arranged on the second surface of the insulating film 501. The semiconductor components 532 producing large amounts of heat are fixed in the space surrounded by the external terminals 503. Therefore, this reduces the packaging density of the semiconductor device. After the device has been installed, the strength of the printed wiring board can be enhanced. Heat generated by the semiconductor device 532 can be effectively dissipated. Other components are less affected.

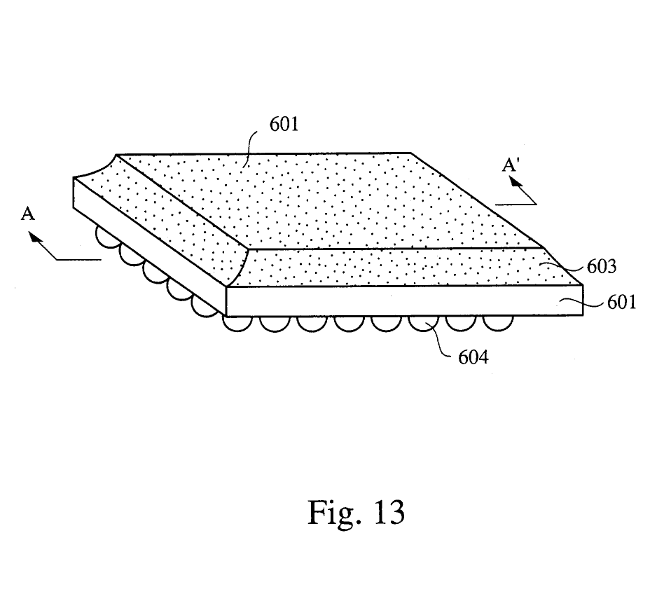

A fifth embodiment of the invention is next described by referring to FIGS. 13-15. In this fifth embodiment, first and second semiconductor components are packed on opposite surfaces of a printed wiring board. This embodiment is characterized in that the rear surfaces of the first and second semiconductor components are exposed.

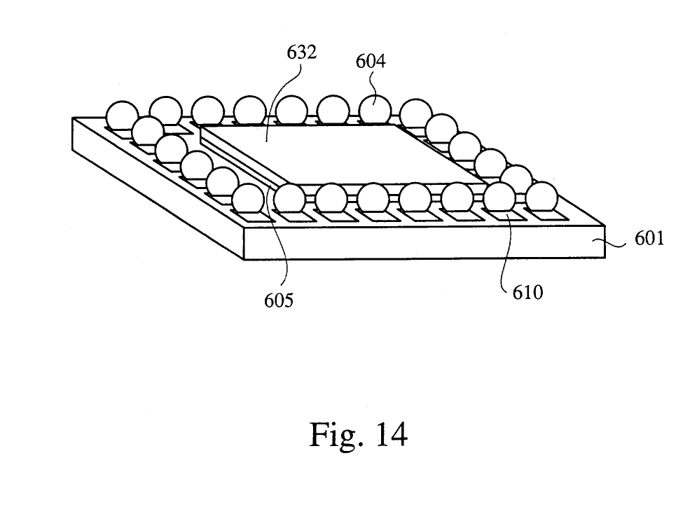

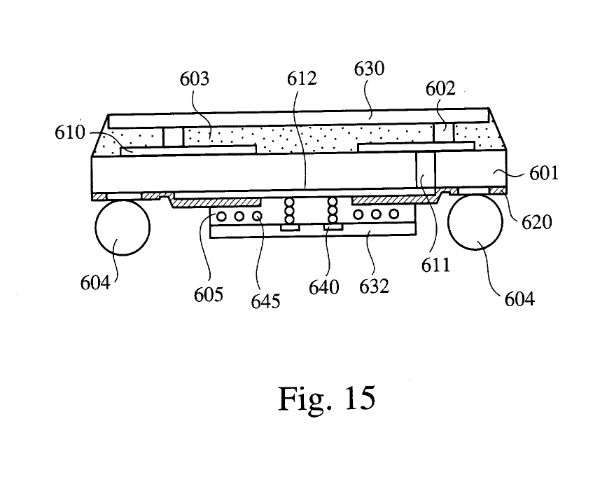

FIG. 13 is a perspective view of the semiconductor device, as viewed from the first surface on the opposite side of the external terminals. FIG. 14 is a perspective view of the semiconductor device, as viewed from the second surface on the side of the external terminals. FIG. 15 is a cross-sectional view taken on line A-A′ of FIG. 13. The semiconductor device in accordance with the present embodiment comprises a printed wiring board 601, semiconductor components 630 having bumps 602 acting as terminals for making connections with an external circuit, ball-like external terminals 604 bonded to conductive interconnects on the opposite surface, and semiconductor components 632 connected with the surface on the side of the external terminals via an anisotropic conductive film 605. Conductive interconnects 610 are formed on both surfaces of the printed wiring board 601. A layer of metallization 611 is buried in holes extending through the board to connect the conductive interconnects 610 on both surfaces. A solder resist 620 is patterned in a desired shape on the surface on the side of the external terminals. The external terminals 604 are electrically connected with those portions of the surface of the printed wiring board 601 on the side of the external terminals to which the solder resist 620 is not applied. Semiconductor components 630 are connected with the conductive interconnects 610 on the surface on the opposite side of the external terminals by the bumps 602. The components are electrically coupled to the external terminals 604 via holes extending through the board.

A potting resin 603 made of epoxy resin or the like is inserted between each semiconductor component 630 and the printing wiring board 601. The potting resin 603 coats the side surfaces of the semiconductor components 630, the terminals 602 of the semiconductor components 630, conductive interconnects 610 formed on the first surface of the printed wiring board 601, etc. Terminals 640 of the semiconductor components 632 packed on the second surface on the side of the external terminals are electrically connected with conductive interconnects 610 on the surface on the side of the external terminals of the printed wiring board 601 by spheres of a metal 645 such as copper existing inside the anisotropic conductive film 605.

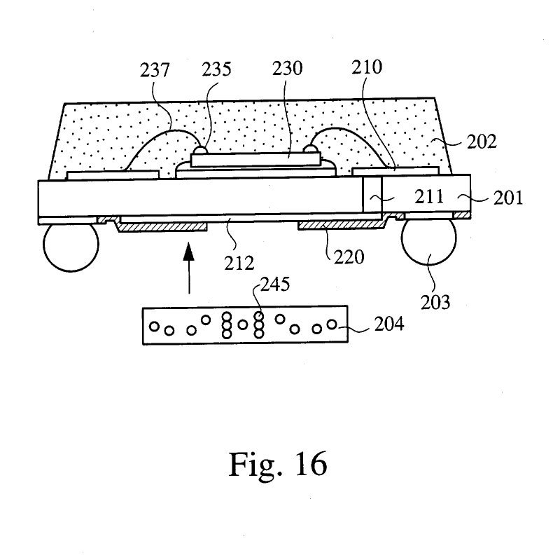

In the fifth embodiment described above, the external terminals 604 are arranged on the second surface of the printed wiring board. The semiconductor components 632 producing large amounts of heat are fixed by the anisotropic conductive film 605 in the space surrounded by the external terminals 604. This reduces the packaging density of the semiconductor device. When the device is installed, the strength of the printed wiring board can be enhanced. Heat generated by the semiconductor components 632 can be effectively dissipated. Other components are less affected. Process sequences for fabricating the illustrated semiconductor devices are hereinafter described by referring to cross sections of FIGS. 16-27.

FIGS. 16-18 illustrate a method of fabricating the semiconductor device in accordance with the first embodiment illustrated in FIG. 9. The semiconductor components 230 are packed on the first surface of the printed wiring board 201. The terminals 235 formed on the semiconductor components 230 are electrically connected with the conductive interconnects 210 formed on the first surface by the bonding wires. The first surface of the printed wiring board 201 is coated with the transfer-molded plastic package 202. The external terminals 203 are mounted around the periphery of the second surface. A space is left around the center. The solder resist pattern 220 is formed on the second surface. The anisotropic conductive film 204 in which the metal spheres 245 are dispersed are mounted to the second surface of the printed wiring board 201 constructed in this way. This state is shown in FIG. 16.

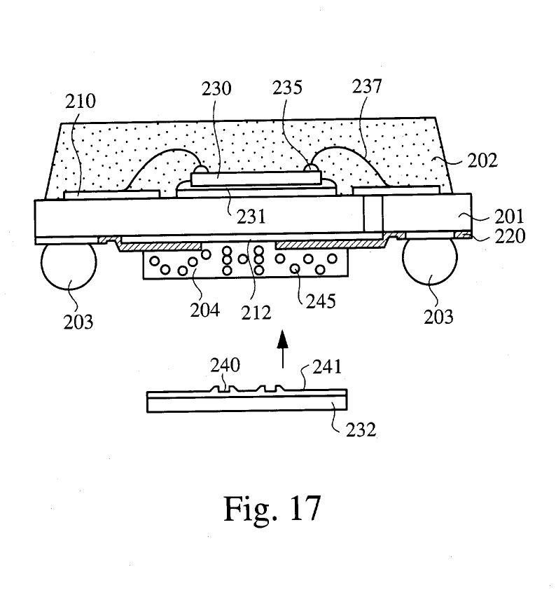

Semiconductor components 232 producing large amounts of heat are prepared. The surfaces of the semiconductor components 232 are coated with a protective film 241 such as a silicon oxide film. The connector terminals 240 are exposed from this protective film 241. This state is shown in FIG. 17.

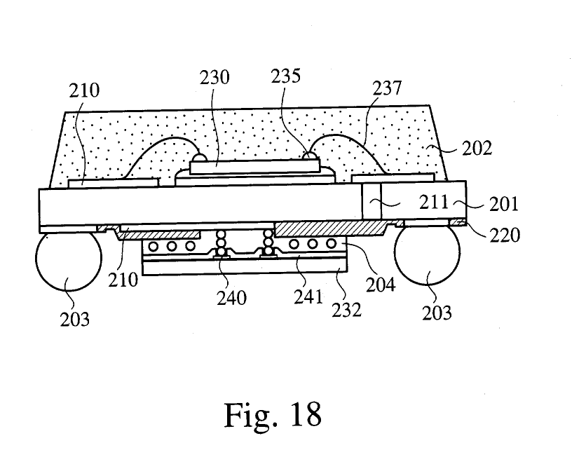

Then, the semiconductor components 232 are pressed against the anisotropic conductive film 204 and fixed to the printed wiring board 201. At this time, the metal spheres 245 inside the anisotropic conductive film 204 electrically connect the conductive interconnects 210 on the second surface with the terminals 240 of the semiconductor components 232, thus completing a semiconductor device. This state is shown in FIG. 18.

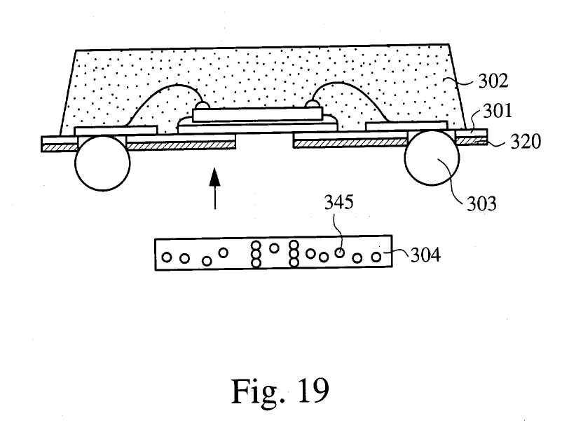

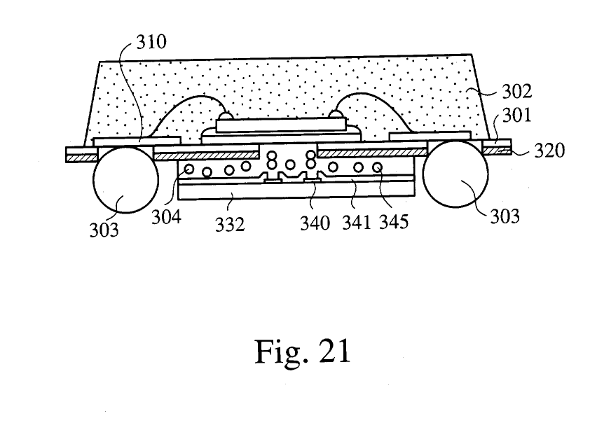

A process sequence for fabricating a semiconductor device in accordance with the second embodiment (FIG. 10) of the invention is described by referring to cross sections of FIGS. 19-21. FIG. 21 is a cross-sectional view of the semiconductor device comprising an insulating film having conductive interconnects thereon. Semiconductor components are packed on the film. The plastic package 302 sealing one side, a first surface, of the insulating film 301 and the external electrodes 303 bonded to the other surface, or a second surface, are formed. The conductive interconnects 310 are formed on the first surface of the insulating film 301. The solder resist pattern 320 is formed on the second surface. The external terminals 303 are electrically connected with those exposed portions of the conductive interconnects 310 to which the solder resist is not applied via holes extending through the insulating film 301. The anisotropic conductive film 304 in which the metal spheres 345 are dispersed is mounted to the second surface of the insulating film 301 constructed in this manner. This state is shown in FIG. 19.

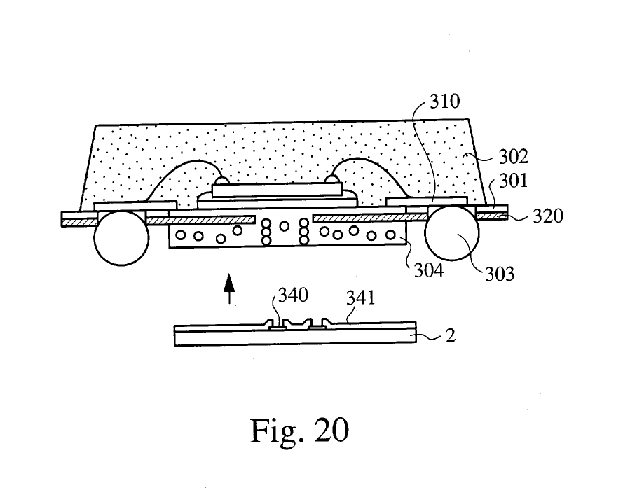

Then, semiconductor components 332 producing large amounts of heat are prepared. The surfaces of the semiconductor components 332 are coated with a protective film 341 such as a silicon oxide film. Connector terminals 340 are exposed from this protective film 341. This state is shown in FIG. 20.

Then, the semiconductor components 332 are pressed against the anisotropic conductive film 304 and fixed to the insulating film 301. At this time, the metal spheres 345 inside the anisotropic conductive film 304 form an electrically conductive path, thus electrically connecting the exposed portions of the conductive interconnects 310 on the first surface with the terminals 340 of the semiconductor components 332. In this way, a semiconductor device is completed. This state is shown in FIG. 21.

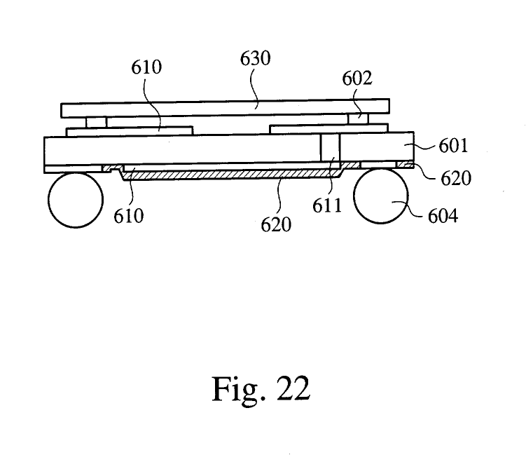

A process sequence for fabricating a semiconductor device in accordance with the fifth embodiment (FIG. 15) of the invention is described by referring to cross sections of FIGS. 22-25. The printed wiring board 601 has the semiconductor components 630 and the external terminals 604. The semiconductor components 630 have the bumps 602 acting as terminals for making connections with an external circuit. The external terminals 604 are bonded to the conductive interconnects 610 on the opposite surface. The semiconductor components 630 and the external terminals 604 are mounted on the printed wiring board 601. The solder resist 620 is patterned into a desired shape on the second surface on the side of the external terminals. The external terminals 604 are mounted around the periphery of the second surface. A space is left around the center. The bumps 602 are connected with conductive interconnects 610 on the second surface. A gap is formed between the surfaces of the semiconductor components 630 opposite to the printed wiring board 601 and the second surface. This state is shown in FIG. 22.

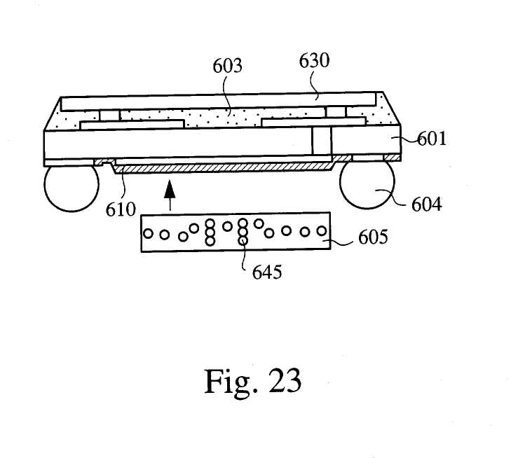

Under this condition, the potting resin 603 consisting of epoxy resin or the like is injected into the gap between each semiconductor component 630 and the printed wiring board 601. The potting resin 603 coats the side surfaces of the semiconductor components 630, the terminals 602 of the semiconductor components 630, the conductive interconnects 610 formed on the first surface of the printed wiring board 601, etc. Then, an anisotropic conductive him 605 in which metal spheres 645 are dispersed is mounted to the second surface of the printed wiring board 601. This state is shown in FIG. 23.

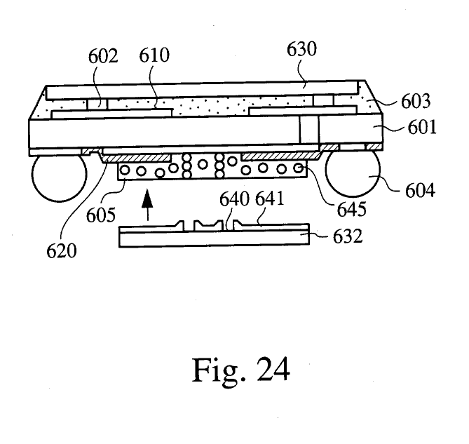

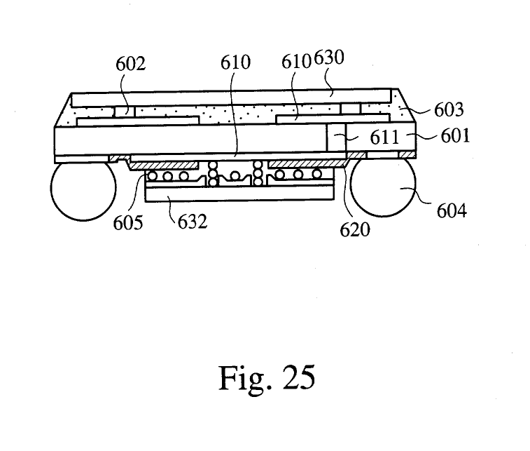

Then, semiconductor components 632 producing large amounts of heat are prepared. The surfaces of the semiconductor components 632 are coated with a protective him 641 such as a silicon oxide film. The connector terminals 640 are exposed from this protective film 641. Subsequently, the semiconductor components 632 are pressed against the anisotropic conductive film 605 and fixed to the printed wiring board 601. At this time, the metal spheres 645 inside the anisotropic conductive him 605 form an electrically conductive path and electrically connect the conductive interconnects 610 formed on the second surface with the terminals 640 of the semiconductor components 632, thus completing a semiconductor device. This state is shown in FIGS. 24 and 25.

In the embodiments of the invention, the anisotropic conductive film is used. This assures that semiconductor components on the surface on the side of the external terminals are attached to a printed wiring board. Installing the semiconductor components on the side of the external terminals makes it possible to reduce the packaging density by 30 to 50%.

When a semiconductor device is connected with conductive interconnects on a mother board with the prior art technique, there is no means for controlling the height of the external terminals. Depending on the pitch between the conductive interconnects, adjacent external terminals may be shorted to each other at some locations. The height of the final package assembly can be adjusted by the total thickness of the combination of the semiconductor device and the anisotropic conductive film.

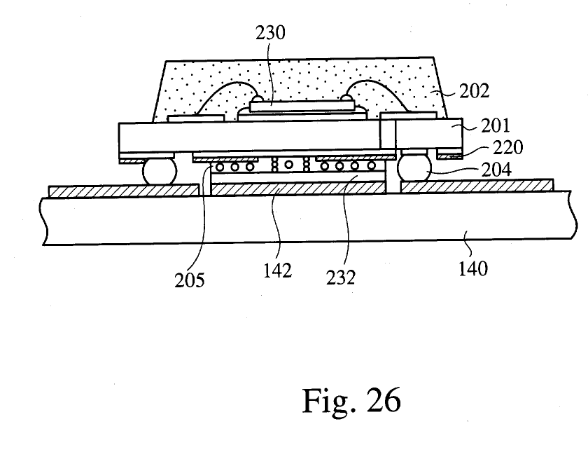

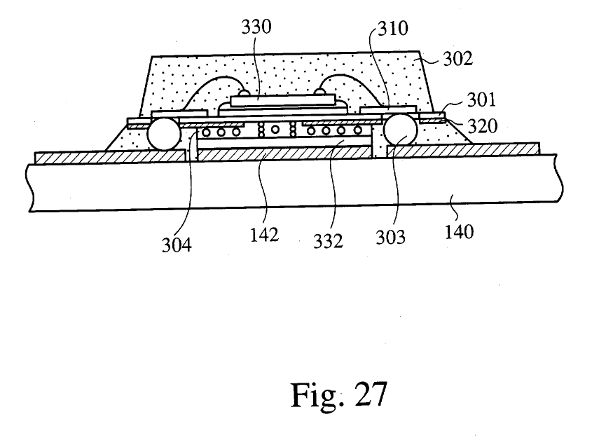

An example of mounting a semiconductor device in accordance with the present invention to a mother board is next described by referring to FIGS. 26 and 27. The mother board, indicated by numeral 140, has a surface on which semiconductor components or chips are packed. A layer of metallization 142 is patterned into conductive interconnects on this surface. FIG. 26 shows an example of mounting the semiconductor device shown in FIG. 9 to the mother board 140. A printed wiring board 201 has a plastic package 202 on its first surface. The board 201 has external terminals 204 on its second surface. Semiconductor components 232 are connected to the second surface via an anisotropic conductive film 205. The external terminals 204 are coupled to the conductive interconnects 142 formed on the mother board 140. Although the semiconductor components 232 are placed on the conductive interconnects 142, the semiconductor components 232 are not electrically connected with the interconnects.

The packaging density of the semiconductor device in accordance with the first embodiment of the invention can be reduced because semiconductor components are packed on the surface of the printed wiring board on the side of the external terminals. When the components are packed, the printed wiring board is brought into intimate contact with the mother board 140 via the semiconductor components 232 and via the external terminals 204. Hence, the rigidity of the printed wiring board 201 can be improved. If the semiconductor components produce large amounts of heat, it can be directly dissipated from the mother board after the semiconductor components have been packed. Furthermore, the height of the final package assembly can be adjusted by the total thickness of the integrated circuit and the anisotropic conductive film above the surface on the side of the external terminals.

FIG. 27 shows an example of mounting the semiconductor device in accordance with the second embodiment shown in FIG. 10 to the mother board 140. The insulating film 301 has the plastic package 302 on its first surface. The film 301 has the external terminals 303 on its second surface. The semiconductor components 332 producing large amounts of heat are connected to the surface on the side of the external terminals via the anisotropic conductive film 304. The external terminals 303 are bonded to the conductive interconnects 142 formed on the mother board 140. At this time, the semiconductor components 332 are also placed on the conductive interconnects 142 but not electrically connected with the interconnects. After packaging, potting resin is inserted between the insulating film 301 and the mother board 140. The height of the final package assembly can be adjusted. In addition, a reliable semiconductor device can be offered at low price.

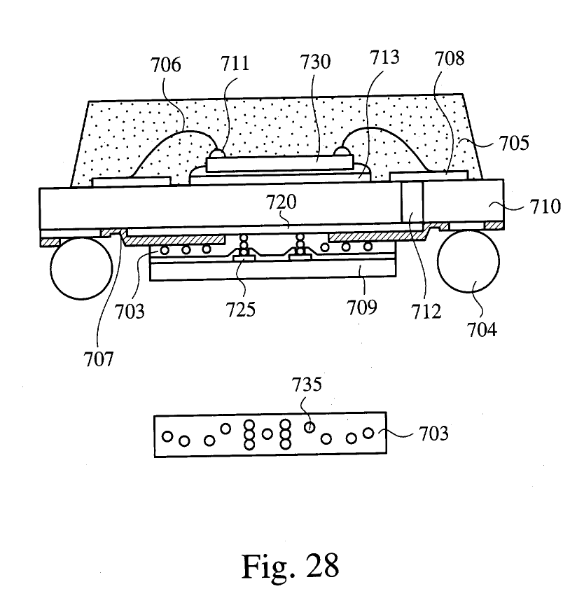

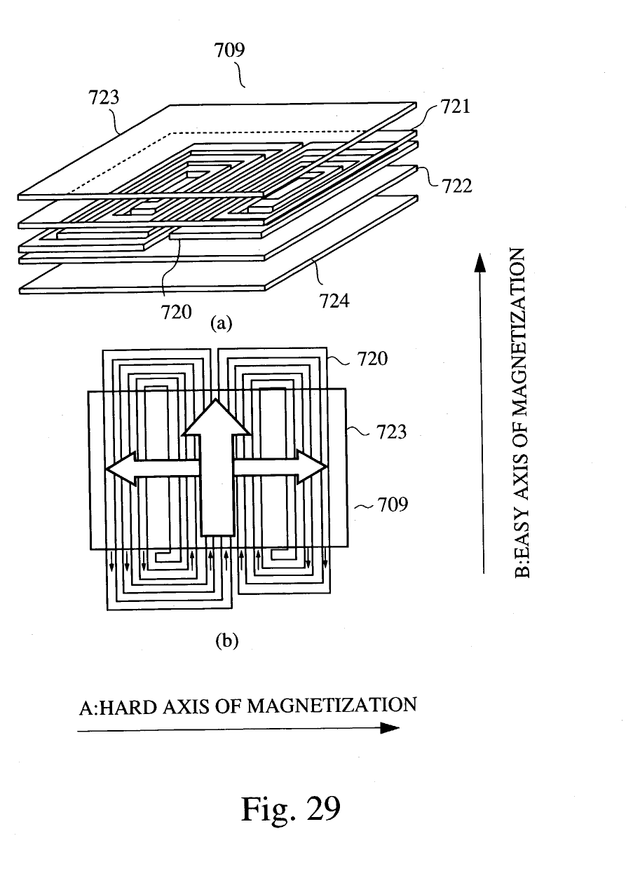

A sixth embodiment of the invention is next described by referring to FIGS. 28, 29(a), 29(b), and 30. FIG. 28 is a cross-sectional view of a semiconductor device in accordance with the invention, the semiconductor device being equipped with semiconductor components and a thin-film inductor. FIG. 29(a) is a perspective view of the thin-film inductor packed on the semiconductor device. FIG. 29(b) is a plan view of this thin-film inductor. As shown in FIG. 28, the semiconductor device comprises a transfer-molded plastic package 705 sealing one side, or a first surface, of a printed wiring board 710, ball-like external terminals 704 bonded to the other side, or a second surface, and the thin-film inductor 709, connected to the second surface via an anisotropic conductive film 703. Conductive interconnects 708, 713 and 720 made of aluminum or other material are formed on opposite sides of the printed wiring board 710. These conductive interconnects 708, 713 and 720 are electrically connected together by a layer of metallization 712 buried in holes extending through the board. A solder resist pattern 707 is formed on the second surface. The external terminals 704 are electrically connected with those portions of the second surface of the printed wiring board 710 to which the solder resin is not applied.

Semiconductor components 730 are connected to the first surface with adhesive. Terminals 711 of the semiconductor components 730 are electrically connected with conductive interconnects 708 formed on the first surface of the printed wiring board 710 by means of bonding wires 706. The plastic package 705 coats the conductive interconnects 708 on the first surface of the printed wiring board 710, the adhesive, the bonding wires 706, the semiconductor components 730, etc. Terminals 725 of the thin-film inductor 709 on the side of the external terminals, or on the second surface, are connected with the conductive interconnects 720 formed on the second surface of the printed wiring board 710 by metal spheres 735 inside the anisotropic conductive film 703. For example, the anisotropic conductive film 703 consists of a film of a synthetic resin such as polyimide in which spheres 735 of a metal such as silver are dispersed. When pressure is applied to a part of the film surface, the dispersed metal spheres contact each other, forming an electrically conductive path.

As shown in FIG. 29, the thin-film inductor 709 comprises a first soft magnetic material thin film 724, a first interlayer dielectric film 722 coating the first soft magnetic material thin film 724 and consisting of a silicon oxide film, for example, a rectangular double spiral coil 720 fabricated on the first interlayer dielectric film 722 and made of a conductor such as copper, a second interlayer dielectric film 721 coating the coil 720 and made of a silicon oxide film, for example, and a second soft magnetic material thin film 723 coating the interlayer dielectric film 721 and made of an amorphous metal or the like. The first soft magnetic material thin film 724 is 1 to 2 mm thick, for example, and consists of an amorphous metal deposited on a board. Each of the soft magnetic material thin films 723 and 724 has uniaxial anisotropy and possesses an axis of hard magnetization A and an axis of easy magnetization B. When an electrical current flows through the coil 720, an eddy current loss normally occurs. At the same time, a large amount of heat is produced. To reduce this eddy current loss, it is necessary to shape the coil 720 into a rectangle having a major axis parallel to the axis of easy magnetization A.

In the present embodiment, this coil may also be a single-spiral coil consisting of a pair of flat rectangular spiral coils that produces a magnetic field. The first and second soft magnetic material thin films 724 and 723, respectively, have uniaxial magnetic anisotropy. The axis of easy magnetization of these soft magnetic material thin films 723 and 724 is parallel to the major axis of the rectangular coils. Since both double-spiral and single-spiral coils are rectangular, one side of the thin-film inductor 709 is longer than the other side, i.e., the inductor is rectangular. In the sixth embodiment of the invention, the external terminals 704 are arranged on the second surface of the printed wiring board 710, and the thin-film inductor 709 is fixed in the space surrounded by the external terminals 704 by the anisotropic conductive film 703. Hence, the packaging density of the semiconductor device can be decreased. Furthermore, after packaging, the printed wiring board 710 is held to the mother board by the external terminals 704 and by the thin-film inductor 709. Therefore, the strength of the printed wiring board 710 can be enhanced. Although the thin-film inductor produces a large amount of heat, it is exposed from the package 705 and so other components are less affected. The semiconductor devices equipped with the thin-film inductor are used in micropower supplies for DC/DC converters, magnetic sensors, and so on including control semiconductor integrated circuit (control IC) components.

In the present invention, the anisotropic conductive film 703 connects together the thin-film inductor 709 and the printed wiring board 720, as shown in FIG. 28, and so the junction area of the region acting as a pad can be made large. Consequently, a large current can be supplied. It can be expected that the thin-film inductor 709 will be bonded stably. In the prior art technique, a thin-film inductor is connected to a printed wiring board by means of bonding wires. In the present invention, a region for making connections with the conductive interconnects 720 is formed immediately above the center of the thin-film inductor 709. Therefore, it is not necessary to form a bonding pad region around the periphery, unlike the prior art technique. The area of the printed wiring board occupied by the thin-film inductor can be decreased. Furthermore, no bonding wires pass over the inductor; otherwise an electrical current flowing through the bonding wires would produce undesired inductance. Therefore, the designed inductance can be accurately obtained.

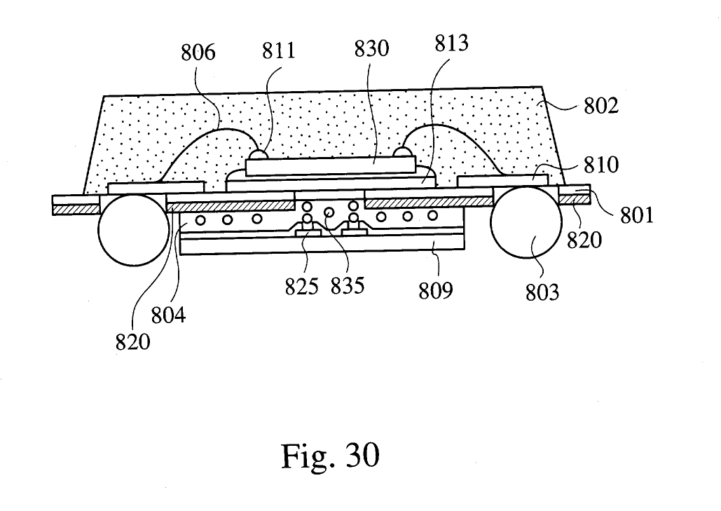

FIG. 30 is a cross-sectional view of a semiconductor device comprising an insulating film having a layer of metallization. Semiconductor components and a thin-film inductor are packed on this film. This semiconductor device comprises a transfer-molded plastic package 802 sealing one side, or a first surface, of the insulating film 801, ball-like external terminals 804 bonded to the other side, or a second surface, and a thin-film inductor 809 connected to the surfaces of the external terminals via an anisotropic conductive film 804. Metallization 810 of aluminum or other material is formed on the first surface of the insulating film 801. The external terminals 810 are electrically connected via holes extending through the film 801 with the exposed portions of the metallization 810 at locations of the insulating film 801 where the solder resist is not present.

Semiconductor components 830 are connected to the first surface of the insulating film 801 via adhesive 813. The terminals 811 of the semiconductor components 830 are electrically connected with the metallization 808 formed on the first surface by means of bonding wires 806. The plastic package 802 coats the metallization 810 on the first surface of the insulating film 801, the adhesive 813, the bonding wires 806, the semiconductor components 830, etc. Terminals 825 of the thin-film inductor 809 on the side of the external terminals, or the second surface, are connected with the exposed portions of the metallization 810 by metal spheres 835 inside the anisotropic conductive film 804. For example, the anisotropic conductive film 804 consists of a film of a synthetic resin such as polyimide in which spheres of a metal such as silver are dispersed. When pressure is applied to a part of the film surface, the dispersed metal spheres contact each other, forming an electrically conductive path.

In the present invention, the external terminals 803 are arranged on the second surface of the insulating film 815. The thin-film inductor 809 is fixed in the space surrounded by the external terminals 803 by the anisotropic conductive film. This reduces the packaging density of the semiconductor device. Furthermore, after packaging, the rigidity of the printed wiring board can be enhanced. The semiconductor device equipped with the thin-film inductor is used in micropower supplies for DC/DC converters, magnetic sensors, and so on including control semiconductor integrated circuit (control IC) components.

In the present invention, the anisotropic conductive film 804 connects together the thin-film inductor 809 and the printed wiring board 820, as shown in FIG. 30, and so the junction area of the region acting as a pad can be rendered large. Consequently, a large current can be supplied. It can be expected that the thin-film inductor 809 will be bonded stably. In the prior art technique, a thin-film inductor is connected to a printed wiring board by means of bonding wires. In the present invention, a region for making connections with the conductive interconnects 810 is formed immediately above the center of the thin-film inductor 809. Therefore, it is not necessary to form a bonding pad region around the periphery, unlike the prior art technique. The area of the printed wiring board occupied by the thin-film inductor can be decreased. Furthermore, no bonding wires pass over the inductor; otherwise an electrical current flowing through the bonding wire would produce undesired inductance.

As described thus far, the present invention can reduce the packaging density of a semiconductor device by packing semiconductor components (semiconductor IC components) on the surface on the side of the external terminals of a printed wiring board.

Furthermore, when the printed wiring board is mounted to a mother board, the rigidity of the printed wiring board can be enhanced. If the semiconductor components produce large amounts of heat, it can be directly dissipated from the mother board when the printed wiring board is mounted to the mother board. Moreover, the height of the final package assembly can be adjusted by the total thickness of the integrated circuit and the anisotropic conductive film above the surface on the side of the external terminals. Where the printed wiring board is replaced by an insulating film, a low-cost semiconductor device can be provided.

While there have been illustrated and described what are presently considered to be preferred embodiments of the present invention, it will be understood by those skilled in the art that various changes and modifications may be made, and equivalents may be substituted for devices thereof without departing from the true scope of the invention. In addition, many modifications may be made to adapt a particular situation or material to the teachings of the present invention without departing from the central scope thereof. Therefore, it is intended that this invention not be limited to the particular embodiments disclosed as the best mode contemplated for carrying out this invention, but that the invention include all embodiments falling within the scope of the appended claims.

1. A semiconductor device comprising:
a mounting material having a first surface and a second surface;
a first semiconductor integrated circuit mounted on the first surface of said mounting material;
a plurality of external terminals formed on the second surface of said mounting material; and
a second semiconductor integrated circuit mounted on the second surface of said printed wiring board.

2. A semiconductor device according to claim 1, wherein said external terminals are formed around a periphery of said second surface of said mounting material, and wherein said second semiconductor integrated circuit is mounted in a region inside said periphery.

3. A semiconductor device according to claim 2, wherein said external terminals comprise deformable ball-shaped terminals.

4. A semiconductor device according to claim 1, wherein said external terminals comprise deformable ball-shaped terminals.

5. A semiconductor device according to claim 1, wherein said second semiconductor integrated circuit is lower in height than said external terminals.

6. A semiconductor device according to claim 1, wherein said second semiconductor integrated circuit produces a larger amount of heat than said first semiconductor integrated circuit.

7. A semiconductor device according to claim 1, comprising:
conductive interconnects formed on said first and second surfaces of said mounting material;
wherein said first and second semiconductor integrated circuits are connected via said conductive interconnects.

8. A semiconductor device according to claim 1, further comprising:
conductive interconnects formed on said first and second surfaces of said mounting material; and
an anisotropic conductive film for connecting said second semiconductor integrated circuit with said conductive interconnects.

9. A semiconductor device according to claim 1, wherein said mounting material comprises a printed circuit board.

10. A semiconductor device according to claim 1, wherein said mounting material comprises a film substrate.

11. A semiconductor device according to claim 1, wherein:
said external terminals comprise a ball grid array formed on said second surface of said mounting material and having a portion where no balls are arranged; and
said second semiconductor integrated circuit is mounted in said portion.

12. A semiconductor device comprising:
a substrate having a first surface and a second surface;
a semiconductor integrated circuit disposed on said first surface of said substrate;
external terminals formed on said second surface of said substrate; and
a thin-film inductor formed on said second surface of said substrate.

13. A semiconductor device according to claim 12, wherein said thin-film inductor further comprises a coil and a soft magnetic material for holding said coil therein, and wherein said soft magnetic material has an axis of easy magnetization and an axis of hard magnetization.

14. A semiconductor device according to claim 13, wherein said coil is rectangular in shape and has a major axis parallel to said axis of hard magnetization of said soft magnetic material.

15. A semiconductor device according to claim 12, wherein said external terminals are formed around a periphery of said second surface of said substrate, and wherein said thin-film inductor is mounted in a region inside said periphery.

16. A semiconductor device according to claim 12, wherein said thin-film inductor is lower in height than said external terminals.

17. A semiconductor device according to claim 12, wherein said thin-film inductor produces a larger amount of heat than said semiconductor integrated circuit.

18. A semiconductor device according to claim 12, comprising:
conductive interconnects formed on said first and second surfaces of said substrate;
wherein said semiconductor integrated circuit and said thin-film inductor are connected via said conductive interconnects.

19. A semiconductor device according to claim 12, further comprising:
conductive interconnects formed on said first and second surfaces of said substrate; and
an anisotropic conductive film for connecting said thin-film inductor with said conductive interconnects.

20. A semiconductor device according to claim 12, further comprising a plastic package that covers said semiconductor integrated circuit on said substrate.

21. A semiconductor device according to claim 12, wherein said substrate comprises a film substrate.

22. A semiconductor device according to claim 12, wherein:
said external terminals comprise a ball grid array formed on said second surface of said substrate and having a portion where no balls are arranged; and
said thin film inductor is mounted in said portion.
